(19) United States
(12) Patent Application Publication
(10) Pub. No.: US 2021/0226151 A1
(43) Pub. Date: Jul. 22, 2021

(54) ELECTRODE AND MANUFACTURING METHOD THEREOF AND ORGANIC ELECTROLUMINESCENT DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Toru KIMURA, Wuhan, Hubei (CN)

(21) Appl. No.: 16/303,280

(22) PCT Filed: Aug. 8, 2018
(86) PCT No.: PCT/CN2018/099399

§ 371 Date: Nov. 20, 2018

(30) Foreign Application Priority Data
Jun. 13, 2018 (CN) 201810605063.8

(51) Int. Cl. H01L 51/52; H01L 51/50; C23C 14/02; C23C 14/20; C22C 5/06

(52) U.S. Cl. CPC H01L 51/5215; H01L 51/5012; C23C 14/021; C23C 14/20; H01L 51/5092; H01L 51/5072; C22C 5/06; H01L 51/5056; H01L 51/5234

(57) ABSTRACT

The present disclosure provides an electrode having a first indium zinc oxide film, a metal film, and a second indium zinc oxide film which are laminated in sequence, in which the metal film is made of an Ag alloy. The first indium zinc oxide film has a thickness ranging from 5 nm to 40 nm; the metal film has a thickness ranging from 80 nm to 160 nm; and the second indium zinc oxide film has a thickness ranging from 5 nm to 40 nm. The electrode is applicable to organic light emitting diode (OLED) display technology or flexible OLED display technology.

### FIELD OF INVENTION

The present application relates to display technology, and more particularly to an anode structure used for an organic electroluminescent device and a manufacturing method, as well as application of the anode structure.

### BACKGROUND OF INVENTION

Organic light-emitting diode (OLED) display technology have become a new generation flat display technology since they have many excellent characteristics such as self-illumination, low energy consumption, wide viewing angles, rich color, quick response times, and flexible screen applications.

An indium tin oxide (ITO) conductive film serves as an ideal transparent electrode and is widely used in an organic electroluminescent device due to its low resistance, high transmittance, good thermal stability, and the process for manufacturing and patterning the ITO conductive film is simple.

Referring to FIG. 1, this shows a current and widely used organic electroluminescent device. As shown in FIG. 1, the organic electroluminescent device 1 comprises and anode 12 formed on a substrate 10, an organic layer 14, and a cathode 16. In FIG. 1, the organic layer 14 includes an electron injection layer 141, an electron transmission layer 143, a light emitting layer 145, a hole transmission layer 147, and a hole injection layer 149. Usually, the anode 12 is a conductive film including ITO films with high work function and high reflectivity and a metal film (generally silver, Ag) to form a three-layer superimposed ITO/Ag/ITO. The cathode 16 includes a metallic silver with low work function and an alloy of Mg/Ag.

During manufacturing of the above organic electroluminescent device 1, it is necessary to wet-etch the conductive film of the three-layer superimposed ITO/Ag/ITO for manufacturing a required pattern of the electrodes.

Refer to FIG. 2, which shows a flowchart for manufacturing the anode of the above organic electroluminescent device 1. Because the generation of microcrystalline ITO (μC-ITO) causes ITO residue during the wet etching process, the film formation of the first ITO film and the second ITO film are carried out at a low temperature (room temperature) to prevent microcrystallization of ITO in the manufacturing process as shown in FIG. 2. Since the etching rates of the ITO film and the Ag film are different, as shown in FIG. 2, after the first ITO film, the Ag film, and the second ITO film are formed, it is necessary to select different etching solutions to wet-etch the first ITO film, the Ag film, and the second ITO film in sequence, thereby complicating the manufacturing process.

In addition, over-etching is likely to occur when the first ITO film is etched, and over-etching of the ITO film causes the Ag film to be exposed, thereby causing undesirable effects such as vulcanization of the Ag film.

Moreover, since the crystallized ITO can improve the transmittance characteristics of the ITO film, as shown in FIG. 2, it is necessary to further perform an annealing treatment (heat treatment) to crystallize the ITO film after the wet etching treatment. However, in the annealing treatment, crystallization of ITO causes embossing (concavity and convexity) on the surface of the ITO film, and submicron-sized hemispherical protrusions are formed on the surface of the Ag film (that is, the Hillock phenomenon occurs in the Ag film), thereby causing destruction of the film and problems such as short circuiting.

In order to solve the problem that the ITO film and the Ag film need to be etched separately, an ITO/Ag/ITO etching solution dedicated to the AM-OLED display has been developed. The specific etching solution is mainly prepared by filtering and mixing the phosphoric acid, acetic acid, nitric acid, a surfactant, an additive, and pure water. However, the specific etching solution is not stable, and it is difficult to control the etching angle and the etching amount of the Ag film during the etching process, thereby affecting repeatability of the etching effect.

It is therefore necessary to provide a novel electrode material and an organic electroluminescent device using the novel electrode material to solve the problems as described above.

### SUMMARY OF INVENTION

An object of the present invention is to provide a display panel and a method of producing the same to promote the display quality of the display panel.

An object of the present application is to provide an electrode and a manufacturing method of the electrode. The electrode is applicable to an OLED display technology or a flexible OLED display technology. In the organic electroluminescent device, since the indium zinc oxide film of the electrode 3 in this embodiment is an amorphous film which can be etched fast, and the electrode of the organic electroluminescent device can be wet-etched by using only an etching solution and an apparatus of an Ag alloy, so that the etching of the electrode 3 is completed by using the same etching solution on the same etching device, thereby achieving the purpose of simplifying the OLED manufacturing process. In addition, although the indium zinc oxide film is an amorphous film, it has similar transmittance characteristics to the crystallized ITO. Therefore, no annealing treatment is required in the manufacturing process of the electrode 3, thereby avoiding the Hillock phenomenon of the Ag film caused by the high temperature reaction during the annealing treatment.

To achieve above objects, the present application firstly provides an electrode, including a first indium zinc oxide film, a metal film, and a second indium zinc oxide film which are laminated in sequence, wherein the metal film is made of an Ag alloy.

In one embodiment, the first indium zinc oxide film has a thickness ranging from 5 nm to 40 nm; the metal film has a thickness ranging from 80 nm to 160 nm; and the second indium zinc oxide film has a thickness ranging from 5 nm to 40 nm.

In one embodiment, the Ag alloy is a silver palladium copper alloy (Ag—Pd—Cu).

The present application further provides a manufacturing method of the abovementioned electrode, comprising the following steps: step (S1) of providing a film formation substrate; step (S2) of forming a first indium zinc oxide film having a thickness ranging from 5 nm to 40 nm on the film formation substrate; step (S3) of forming a metal film having a thickness ranging from 80 nm to 160 nm on the first indium zinc oxide film; and step (S4) of forming a second indium zinc oxide film having a thickness ranging from 5 nm to 40 nm on the metal film; wherein the metal film is made of an Ag alloy.

In one embodiment, in the step (S1), the film formation substrate is a glass substrate, a polyimide substrate, or a film substrate.

In one embodiment, the Ag alloy is a silver palladium copper alloy (Ag—Pd—Cu).

In one embodiment, the first indium zinc oxide film, the metal film, and the second indium zinc oxide film are formed by a direct current magnetron sputtering process.

In one embodiment, a direct current ranging from 2 kW to 8 kW and a sputtering pressure ranging from 0.2 Pa to 1 Pa are carried out during the direct current magnetron sputtering process.

The skilled person in the art can understand that the direct current magnetron sputtering process can be executed by any known apparatus. For example, in one embodiment, the direct current magnetron sputtering process is carried out in a vacuum coating apparatus. The vacuum coating apparatus can be, but not limited to, a monomer coating equipment, a continuous coating equipment, or an integrated coating equipment.

In one embodiment, the direct current magnetron sputtering process is completed in a film forming chamber of the vacuum coating apparatus. The vacuum degree of the film forming chamber is below 4×10⁻⁵ Pa. An inert gas is used for the sputtering gas, for example, but not limited to, argon (Ar) gas. In addition, alternatively, in the step (S2) and the step (S4) of forming the first indium zinc oxide film and the second indium zinc oxide film, the Ar gas can be added with oxygen (O₂) or hydrogen (H₂), and control a volume percentage of the oxygen to be 0.1% to 5% and the flow rate of the hydrogen to be 1-10 standard ml/min (sccm).

in one embodiment, in the step (S2) and the step (S4) of performing the direct current magnetron sputtering process by using indium zinc oxide target. The indium zinc oxide target contains Zn, the content of Zn is 1-10 wt %. In the step (S3), the direct current magnetron sputtering process is performed by using silver palladium copper alloy target.

Therefore, an specific embodiment of the present application is to provide a manufacturing method of an electrode, comprising following steps: step (S1) of providing a film formation substrate; step (S2) of using indium oxide target to carry out a direct current magnetron sputtering process, so as to form a first indium zinc oxide film having a thickness ranging from 5 nm to 40 nm on the film formation substrate; step (S3) of using silver palladium copper alloy target to carry out a direct current magnetron sputtering process, so as to form a metal film having a thickness ranging from 80 nm to 160 nm on the first indium zinc oxide film; and step (S4) of using indium zinc oxide target to carry out a direct current magnetron sputtering process, so as to form a second indium zinc oxide film having a thickness ranging from 5 nm to 40 nm on the metal film; wherein a direct current ranging from 2 kW to 8 kW and a sputtering pressure ranging from 0.2 Pa to 1 Pa are carried out during the direct current magnetron sputtering process. In addition, the step (S1) to the step (S4) are carried out in a film forming chamber of the vacuum coating apparatus. The vacuum degree of the film forming chamber is below 4×10⁻⁵ Pa.

The present application further provides an organic electroluminescent device, using the above electrode as an anode of the organic electroluminescent device, organic electroluminescent device organic electroluminescent device

In one embodiment of the present application, the organic electroluminescent device comprises a substrate; and a first electrode, an organic layer, and a second electrode which are disposed in sequence on the substrate, wherein the first electrode is an anode; the second electrode is a cathode. The organic layer comprises an electron injection layer, an electron transmission layer, a light emitting layer, a hole transmission layer, and a hole injection layer which are disposed in sequence. The anode is a IZO/APC/IZO conductive film including a first indium zinc oxide film (In—Zn-Oxide film, IZO film), a metal film (silver palladium copper alloy, Ag—Pd—Cu, APC), and a second indium zinc oxide film. The cathode is made of any known material of cathode, such as a Mg/Ag alloy. The organic layer can also include other functional layers according to specific performances of different organic electroluminescent devices. The different composition of the organic layer does not affect the structure of the anode.

In addition, the present application further provides a display panel, comprising:

a substrate being a glass substrate, a polyimide substrate, or a film substrate;

a thin film transistor device layer formed on the substrate and having a drain; and

an organic electroluminescent device layer formed on the thin film transistor device layer;

wherein the organic electroluminescent device layer comprises a first electrode as being an anode, an organic layer, and a second electrode as being a cathode, the first electrode contact with the drain of the thin film transistor device layer; and

the first electrode comprises a first indium zinc oxide film, a metal film, and a second indium zinc oxide film which are laminated in sequence, wherein the metal film is made of an Ag alloy.

In one embodiment of the present application, the first indium zinc oxide film has a thickness ranging from 5 nm to 40 nm; the metal film has a thickness ranging from 80 nm to 160 nm; and the second indium zinc oxide film has a thickness ranging from 5 nm to 40 nm.

In one embodiment of the present application, the Ag alloy is a silver palladium copper alloy (Ag—Pd—Cu). The skilled person in the art can understand that the silver palladium copper alloy is a well-known and commercially available material. Usually, the silver palladium copper alloy contains silver element of 90-95 wt %, palladium element of 4-8 wt %, and copper element of about 1 wt %.

In order to more clearly illustrate the technical solutions in the embodiment or in the present invention, the following drawings, which are intended to be used in the description of the embodiment or of the present invention, will be briefly described.

### BRIEF DESCRIPTION OF DRAWINGS

FIG. 1 is a schematic view of a current organic electroluminescent device.

FIG. 2 is a flowchart of film formation and etching process of an anode in a current organic electroluminescent device.

FIG. 3 is a schematic view of an electrode according to one embodiment of the present application.

FIG. 4 is a flowchart for manufacturing the electrode according to one embodiment of the present application.

FIG. 5 is a schematic view of an organic electroluminescent device according to the present application.

FIG. 6 is a flowchart of film formation and etching process for an electrode 3 of an organic electroluminescent device 5 in FIG. 5.

FIG. 7 is a schematic view of a display panel according to one embodiment of the present application.

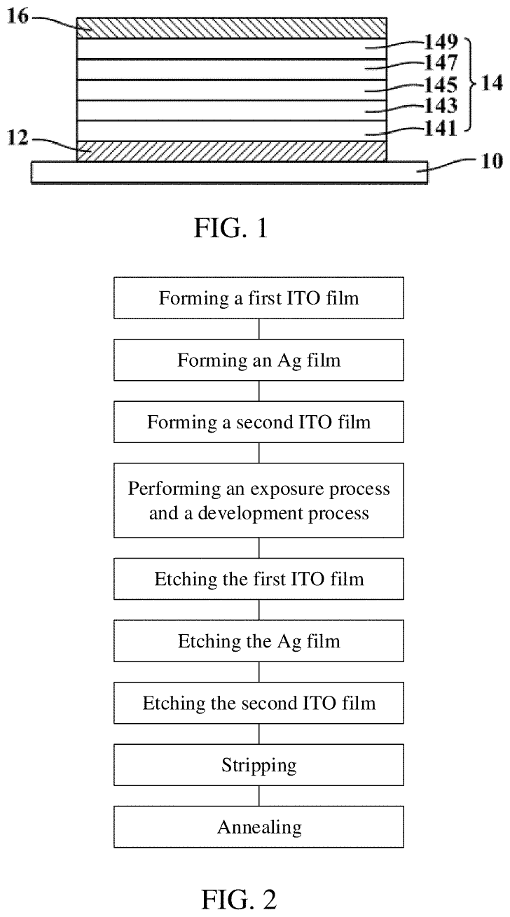

### DETAILED DESCRIPTION OF PREFERRED EMBODIMENTS

The technology of the present application will be described in detail below in combination with specific embodiments. It should be understood that the following specific embodiments are only used to assist those skilled in the art to understand this application and not to limit the application.

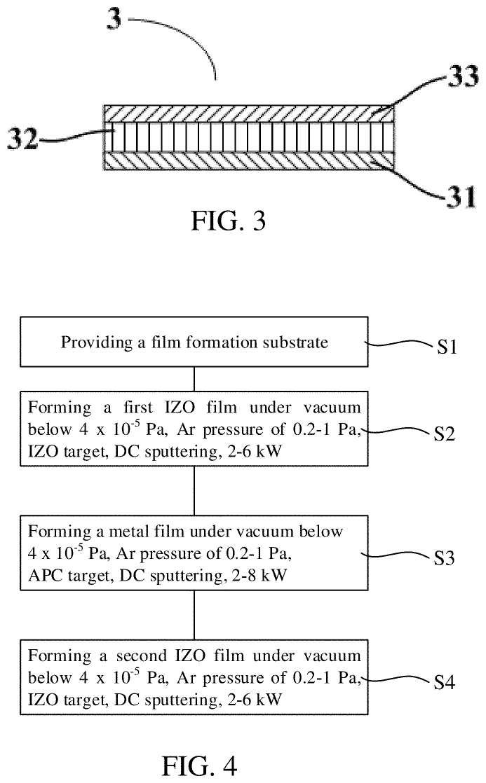

In this embodiment, an electrode 3 is provided. As shown in FIG. 3, the electrode 3 includes a first indium zinc oxide film 31, a metal film 32, and a second indium zinc oxide film 33 which are laminated in sequence.

The first indium zinc oxide film 31 has a thickness ranging from 5 nm to 40 nm; the metal film 32 has a thickness ranging from 80 nm to 160 nm; and the second indium zinc oxide film 31 has a thickness ranging from 5 nm to 40 nm. The metal film 32 is made of a silver palladium copper alloy (Ag—Pd—Cu). The silver palladium copper alloy is a well-known and commercially available material. Usually, the silver palladium copper alloy contains silver element of 90-95 wt %, palladium element of 4-8 wt %, and copper element of about 1 wt %.

As shown in FIG. 4, a manufacturing method of the abovementioned electrode 3 is provided in this embodiment, and the manufacturing method comprises following steps.

Step S1 of providing a film formation substrate. The film formation substrate is a glass substrate, a polyimide substrate, or a film substrate. It can be understood that the film formation substrate has structures formed by several previous processes thereon, for example, it is possible to include an inorganic layer, some layers of a thin film transistor, or a completed thin film transistor and traces. Specifically, the structures are determined according to the film to be formed by the corresponding process in the whole process flow.

Step S2 of placing the substrate obtained by the step S1 in a film forming chamber of a vacuum coating apparatus, and controlling a vacuum degree of the film forming chamber below 4×10⁻⁵ Pa to performing a direct current magnetron sputtering process by using an indium zinc oxide target, so as to form a first indium zinc oxide film having a thickness ranging from 5 nm to 40 nm on the film formation substrate.

Step S3 of using a silver palladium copper alloy target to perform a direct current magnetron sputtering process under same vacuum degree of the step S2, so as to form a metal film having a thickness ranging from 80 nm to 160 nm on the film formation substrate, wherein the Zn content of the indium zinc oxide target is 1-10 wt %.

Step S4 of using an indium zinc oxide target to perform a direct current magnetron sputtering process under same vacuum degree of the step S2, so as to form a second indium zinc oxide film having a thickness ranging from 5 nm to 40 nm on the metal film.

In the direct current magnetron sputtering process, a direct current ranging from 2 kW to 8 kW, a sputtering gas is argon, and a sputtering pressure ranging from 0.2 Pa to 1 Pa are carried out.

The vacuum coating apparatus can be, but not limited to, a monomer coating equipment, a continuous coating equipment, or an integrated coating equipment.

In the step (S2) and the step (S4) of forming the first indium zinc oxide film and the second indium zinc oxide film, the Ar gas can be added with oxygen (O₂) or hydrogen (H₂), and control a volume percentage of the oxygen to be 0.1% to 5% and the flow rate of the hydrogen to be 1-10 standard ml/min (sccm).

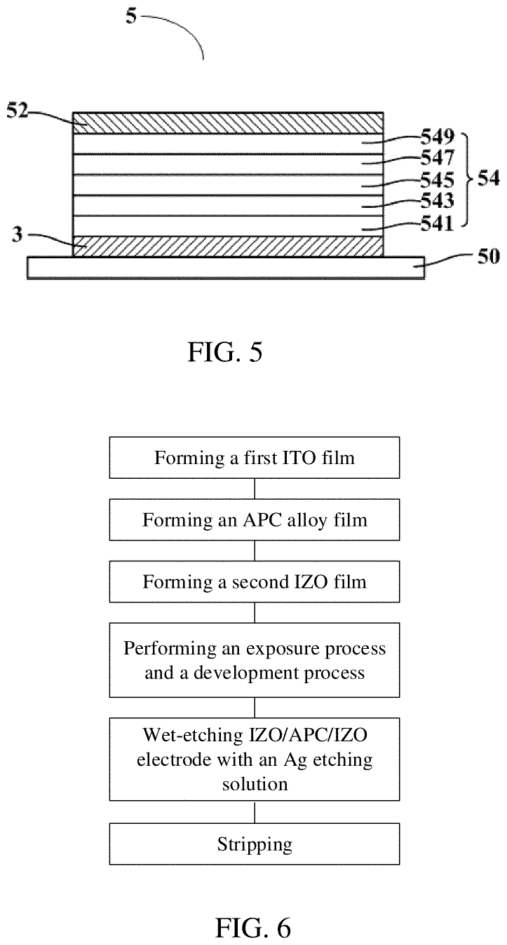

Furthermore, this embodiment provides an organic electroluminescent device 5 as shown in FIG. 5.

As shown in FIG. 5, the organic electroluminescent device 5 has a substrate 50. The substrate 50 can be selected, according to specific applications, from a group consisting of a glass substrate, a polyimide substrate, and a film substrate. It can be understood that the film formation substrate has structures formed by several previous processes thereon, for example, it is possible to include an inorganic layer, some layers of a thin film transistor, or a completed thin film transistor and traces. Specifically, the structures are determined according to the film to be formed by the corresponding process in the whole process flow. On the substrate 50, the electrode 3 as being an anode, an organic layer 54, and a cathode 52 organic electroluminescent device are disposed in sequence.

The organic layer 54 of the electroluminescent device 5 has a structure known in the art, or further includes other accessibility layers. For example, as shown in FIG. 5, the organic layer 54 comprises an electron injection layer 541, an electron transmission layer 543, a light emitting layer 545, a hole transmission layer 547, and a hole injection layer 549.

The skilled person in the art can understand that the abovementioned layers is formed by materials known in the art, and the specific selection of these materials does not affect the implementation of the technical solutions and obtain of the technical effects in the present application.

The cathode 52 is made of metals with lower work functions, such as lithium, magnesium, calcium, strontium, aluminum, or indium, or alloys formed by the metals and copper, gold, or silver, for example but not limited to Al, Mg/Ag alloy. Alternatively, the cathode 52 can be an electrode layer formed by a metal and a metal fluoride alternately, for example but not limited to an electrode formed by lithium fluoride and aluminum layer alternately. Of course, the cathode 52 can also be made of ITO or IZO.

The electron injection layer 541 can be formed by, for example but not limited to, one of graphene, carbon nanotube, ZnO, TiO₂, and Cs₂CO₃.

The electron transmission layer 543 can be formed by, for example but not limited to, one of 4,7-diphenyl-1,10-phenanthroline (Bphen), 1,3,5-tris(N-phenylbenzimidazol-2-yl)benzene (TPBi), Bathocuproine (BCP), Tris(8-hydroxyquinoline)aluminum (Alq3).

The hole transmission layer 547 can be formed by, but not limited thereto, one of aromatic diamines, aromatic triamines, carbazoles, triphenylamines, furan based compounds, spiral compounds, polymer materials.

Refer to FIG. 6, FIG. 6 is a flowchart of film formation and etching process of the electrode 3 of the organic electroluminescent device 5. Compared with FIG. 2, since the indium zinc oxide film of the electrode 3 in this embodiment is an amorphous film which can be etched fast, and the electrode 3 can be wet-etched by using only an etching solution and an apparatus of an Ag alloy, so that the etching of the electrode 3 is completed by using the same etching solution on the same etching device, thereby achieving the purpose of simplifying the OLED manufacturing process. In addition, although the indium zinc oxide film is an amorphous film, it has similar transmittance characteristics to the crystallized ITO. Therefore, no annealing treatment is required in the manufacturing process of the electrode 3, thereby avoiding the Hillock phenomenon of the Ag film caused by the high temperature reaction during the annealing treatment.

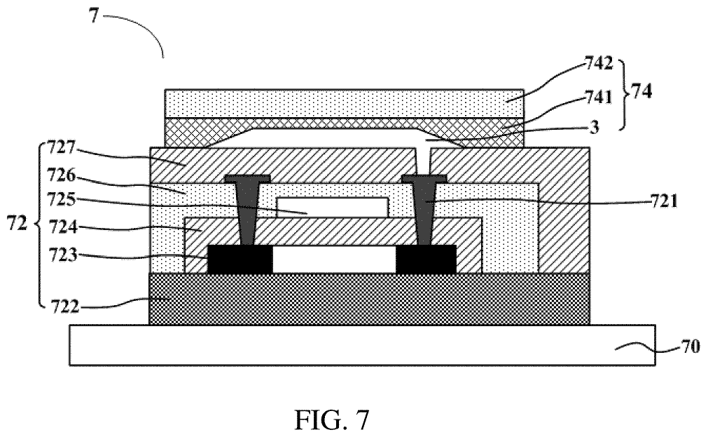

Furthermore, a display panel 7 is provided in this embodiment as referred to FIG. 7. As shown in FIG. 7, the display panel 7 comprises:

a substrate 70, wherein the substrate 70 is a glass substrate, a polyimide substrate, or film substrate;

a thin film transistor device layer 72 formed on the substrate 70 and having a drain 721; and

an organic electroluminescent device layer 74 formed on the thin film transistor device layer 72.

In this embodiment, the organic electroluminescent device layer includes the electrode 3 as being an anode, an organic layer 741, and a second electrode 742 as being a cathode. The electrode 3 contacts with the drain 721 of the thin film transistor device layer 72.

One skilled in the art can understand that the display panel 7 has an essential structure of OLDE display panel as known in the art. for example, as shown in FIG. 7, the thin film transistor device layer 72 includes: a buffer layer 722 formed on the substrate 70, an active layer 723 formed on the buffer layer 722, a gate insulating layer 724 formed on the active layer 723, a gate layer 725 formed on the gate insulating layer 724, an insulating layer 726 formed on the gate layer 725, a source and the drain 721 formed on the insulating layer 726, a planarization layer 727 formed on the source and the drain 721, and the electrode 3 formed on the planarization layer 727.

The present application has been described by the above related embodiments, but the above embodiments are merely examples for implementing the present application. It must be noted that the disclosed embodiments do not limit the scope of the present application. Rather, modifications and equivalent arrangements included in the spirit and scope of the claims are intended to be included within the scope of the present application.

What is claimed is:

1. An electrode for an organic electroluminescent device, wherein the organic electroluminescent device comprises an anode, an organic layer and a cathode formed on a substrate, wherein the electrode includes a first indium zinc oxide film, a metal film, and a second indium zinc oxide film which are laminated in sequence, wherein the metal film is made of an Ag alloy.

2. The electrode for an organic electroluminescent device according to claim 1, wherein the first indium zinc oxide film has a thickness ranging from 5 nm to 40 nm; the metal film has a thickness ranging from 80 nm to 160 nm; and the second indium zinc oxide film has a thickness ranging from 5 nm to 40 nm.

3. The electrode for an organic electroluminescent device according to claim 1, wherein the Ag alloy is a silver palladium copper alloy.

4. A manufacturing method of an electrode for an organic electroluminescent device, comprising steps of:
providing a film formation substrate;
forming a first indium zinc oxide film having a thickness ranging from 5 nm to 40 nm on the film formation substrate;
forming a metal film having a thickness ranging from 80 nm to 160 nm on the first indium zinc oxide film; and
forming a second indium zinc oxide film having a thickness ranging from 5 nm to 40 nm on the metal film;
wherein the metal film is made of an Ag alloy.

5. The manufacturing method according to claim 4, wherein the film formation substrate is a glass substrate, a polyimide substrate, or a film substrate.

6. The manufacturing method according to claim 4, wherein the Ag alloy is a silver palladium copper alloy.

7. The manufacturing method according to claim 4, wherein the first indium zinc oxide film, the metal film, and the second indium zinc oxide film are formed by a direct current magnetron sputtering process.

8. The manufacturing method according to claim 7, wherein a direct current ranging from 2 kW to 8 kW and a sputtering pressure ranging from 0.2 Pa to 1 Pa are carried out during the direct current magnetron sputtering process.

9. An organic electroluminescent device, comprising an anode, an organic layer and a cathode formed on a substrate, wherein the anode is the electrode according to claim 1.

10. The organic electroluminescent device according to claim 9, wherein the organic layer comprises an electron injection layer, an electron transmission layer, a light emitting layer, a hole transmission layer, and a hole injection layer which are disposed in sequence.
